(19) United States
(12) Patent Application Publication
(10) Pub. No.: US 2012/0249184 A1
(43) Pub. Date: Oct. 4, 2012

(54) NARROW PULSE FILTER

(75) Inventors: Charles Derrick Tuten, Scottsdale, AZ (US); Ilker Deligoz, Scottsdale, AZ (US)

(73) Assignee: QUALCOMM INCORPORATED, San Diego, CA (US)

(21) Appl. No.: 13/075,473

(22) Filed: Mar. 30, 2011

(51) Int. Cl. H03K 5/1252

(52) U.S. Cl. 327/34

(57) ABSTRACT

A narrow pulse filter is disclosed. The narrow pulse filter includes a first tri-state inverter. The narrow pulse filter further includes a pulse generator coupled to the first tri-state inverter. The pulse generator is configured to cause the first tri-state inverter to enter a high-impedance state to filter out a narrow pulse from a signal input to the first tri-state inverter.

### TECHNICAL FIELD

The present disclosure relates generally to wireless communication systems. More specifically, the present disclosure relates to systems and methods for a narrow pulse filter.

### BACKGROUND

Wireless devices have become smaller and more powerful in order to meet consumer needs and to improve portability and convenience. Consumers have become dependent upon wireless devices such as cellular telephones, personal digital assistants (PDAs), laptop computers and the like. Consumers have come to expect reliable service, expanded areas of coverage and increased functionality.

Electronic devices may use various circuitry components to convert the analog signals into a usable digital format. Such circuitry components may include mixers, amplifiers, filters, analog-to-digital converters (ADCs), comparators and digital signal processors (DSPs). Each circuitry component may include linear and non-linear portions. Thus, a circuitry component may introduce non-linearities into the received signal, decreasing the sensitivity of the receiver.

Filters have been used to remove some of the non-linearities. However, some filters are unable to remove all the non-linearities, resulting in faulty behavior or even damage to the digital circuitry. Furthermore, some filters may be unable to remove specific non-linearities when incoming digital pulses have specific configurations. Thus, it is desirable to build a better filter for digital signals.

### BRIEF DESCRIPTION OF THE DRAWINGS

FIG. 1 shows a narrow pulse filter for use in the present systems and methods;

FIG. 2 is a circuit diagram illustrating an exemplary embodiment of a narrow pulse filter;

FIG. 3 is a circuit diagram illustrating more specific components of a narrow pulse filter;

FIG. 4 is a timing diagram illustrating waveforms for the input signal A, the Node C and the output signal Y;

FIG. 5 is a block diagram illustrating the ideal transfer function of a narrow pulse filter;

FIG. 6 is a block diagram illustrating an electronic device for use in the present systems and methods;

FIG. 7 is a flow diagram of a method for filtering narrow pulses; and

FIG. 8 illustrates certain components that may be included within an electronic device.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

The detailed description set forth below in connection with the appended drawings is intended as a description of exemplary embodiments of the present invention and is not intended to represent the only embodiments in which the present invention can be practiced. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

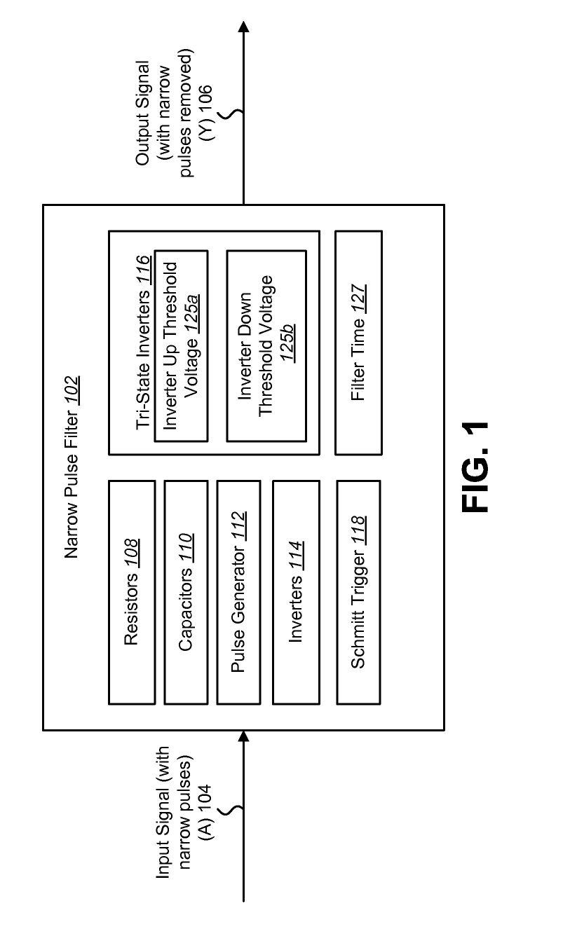

FIG. 1 shows a narrow pulse filter 102 for use in the present systems and methods. The narrow pulse filter 102 of FIG. 1 is an exemplary embodiment of the invention. The narrow pulse filter 102 may be used to remove narrow pulses from a digital signal. Narrow pulses are often found at analog-to-digital interfaces (such as a comparator or an analog-to-digital converter (ADC)). A narrow pulse may be a short-duration electrical pulse in a digital signal. Narrow pulses may cause false operations in circuit components designed to receive and process the digital signal.

In an exemplary embodiment of the invention, the narrow pulse filter 102 may receive an input signal A 104. The input signal A 104 may be a digital signal. The input signal A 104 may include narrow pulses. In one configuration, the narrow pulses in the input signal A 104 may have a duration that is less than 1 nanosecond (ns). Thus, the size of the narrow pulses may be much smaller than the amount of time required to synchronize the input signal A 104 to a clock. For example, it may require 50 ns to 100 ns to synchronize the input signal A 104 to a clock signal. This may be an impractical wait time due to the length of the narrow pulses. In one configuration, there may be no clock for synchronization.

The narrow pulse filter 102 may include resistors 108, capacitors 110, a pulse generator 112, inverters 114, tri-state inverters 116 and a Schmitt trigger 118. A tri-state inverter 116 may be an inverter with three states: a digital logic high output state (i.e., the tri-state inverter 116 outputs a digital logic high output signal), a digital logic low output state (i.e., the tri-state inverter 116 outputs a digital logic low output signal) and a high-impedance state. In the high-impedance state, the influence of the tri-state inverter 116 on the rest of the circuitry may be effectively removed. The Schmitt trigger 118 may be a threshold circuit with positive feedback that has a loop gain greater than 1. In an exemplary embodiment of the invention, the Schmitt trigger 118 may be an inverter with hysteresis. The Schmitt trigger 118 may have an inverter up threshold voltage 125a and an inverter down threshold voltage 125b. In one configuration, the inverter threshold voltages 125a-b of the Schmitt trigger 118 may be greater than the threshold voltage of other inverters 114 used in the narrow pulse filter 102.

The narrow pulse filter 102 may include a filter time 127. The filter time 127 may refer to the resistor/capacitor (RC) circuitry charging time within the narrow pulse filter 102. The filter time 127 represents the smallest pulse width that will be passed through the narrow pulse filter 102 unfiltered.

The narrow pulse filter 102 may remove narrow pulses from the input signal A 104. Thus, the narrow pulse filter 102 may generate an output signal Y 106. The narrow pulses that were present in the input signal A 104 may have been removed in the output signal Y 106. By removing the narrow pulses from the output signal Y 106, the output signal Y 106 may be used in digital circuitry that is sensitive to narrow pulses. For example, the output signal Y 106 may be provided to an asynchronous state machine that controls power P and N field effect transistors (FETS) based upon various inputs. If a signal with narrow pulses is provided to the asynchronous state machine, the asynchronous state machine may enter invalid states and possibly damage the power stage.

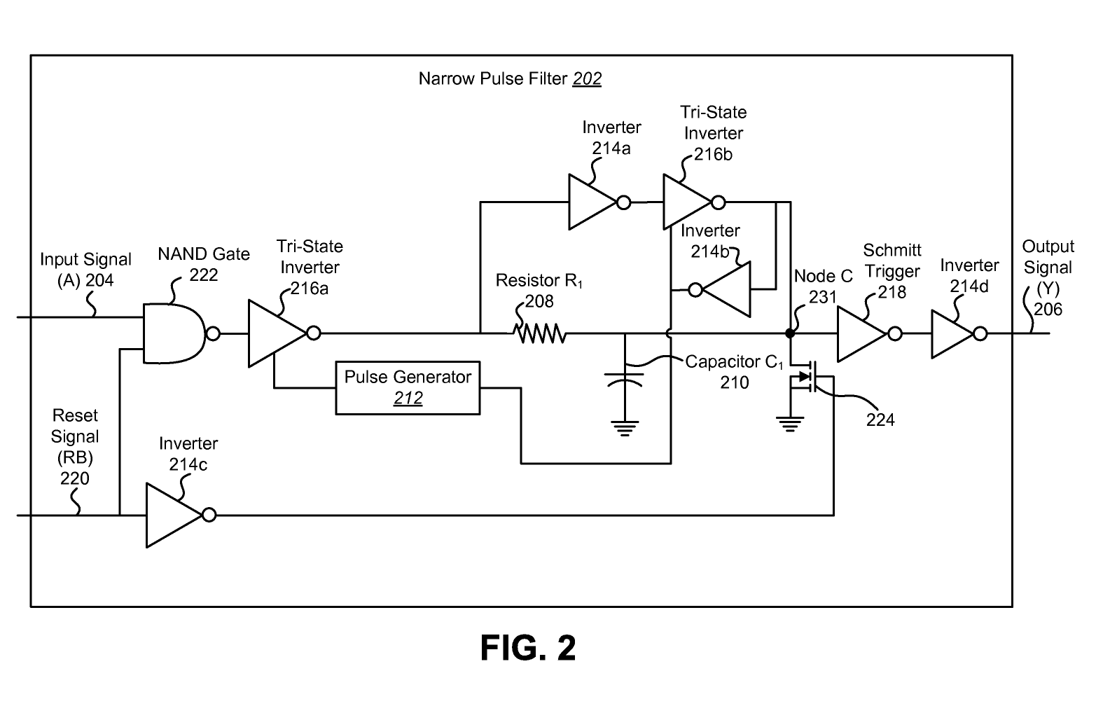

FIG. 2 is a circuit diagram illustrating an exemplary embodiment of a narrow pulse filter 202. The narrow pulse filter 202 of FIG. 2 may be one configuration of the narrow pulse filter 102 of FIG. 1. The narrow pulse filter 202 may remove or reduce narrow pulses in an input signal A 204. Particularly, the narrow pulse filter 202 may remove or reduce narrow pulses in an input signal A 204 when the pulse width of the input signal A 204 is approximately equal to the filter time 127 of the narrow pulse filter 202.

The narrow pulse filter 202 may include a NAND gate 222. The NAND gate 222 may receive an input signal A 204 and a reset signal RB 220. The output of the NAND gate 222 may be input to a first tri-state inverter 216a. As discussed above, a tri-state inverter 216 may operate in one of three states: a digital logic high output state, a digital logic low output state and a high-impedance state. The output of the first tri-state inverter 216a may be coupled to a resistor R1 208. The high-impedance control input of the first tri-state inverter 216a may be coupled to a pulse generator 212. The pulse generator 212 may be used to generate a pulse that causes the first tri-state inverter 216a to enter the high-impedance state. When the first tri-state inverter 216a is in the high-impedance state, the input signal A 204 may be disconnected from the resistor R1 208.

The resistor R1 208 may be coupled to a capacitor C1 210. The capacitor C1 210 may also be coupled to ground. Both the resistor R1 208 and the capacitor C1 210 may be coupled to a Node C 231. The output of the first tri-state inverter 216a may be coupled to an input of a first inverter 214a. The output of the first inverter 214a may be coupled to an input of a second tri-state inverter 216b. The high-impedance control input of the second tri-state inverter 216b may be coupled to the pulse generator 212. The output of the second tri-state inverter 216b may be coupled to the Node C 231. The output of the second tri-state inverter 216b may also be coupled to an input of a second inverter 214b. An output of the second inverter 214b may be coupled to the high-impedance input of the second tri-state inverter 216b. The output of the second inverter 214b may also be coupled to the pulse generator 212.

The Node C 231 may be coupled to the drain of an N-channel enhanced transistor 224. The source of the N-channel enhanced transistor 224 may be coupled to ground. The gate of the N-channel enhanced transistor 224 may be coupled to an output of a third inverter 214c. The third inverter 214c may receive the reset signal RB 220 as an input. The reset signal RB 220 may be a digital logic high during normal operation and a digital logic low when a reset of the narrow pulse filter 202 is desired.

In an exemplary embodiment of the invention, the Node C 231 may also be coupled to the input of a Schmitt trigger 218. The Schmitt trigger 218 may have a higher inverter up threshold voltage 125a than the inverters 114 of the narrow pulse filter 202. The output of the Schmitt trigger 218 may be input to a fourth inverter 214d. The output of the fourth inverter 214d may be the output signal Y 206.

Like other narrow pulse filters 202, when the incoming pulse width of the input signal A 204 is less than the filter time 127, the output signal Y 206 may not include the pulse of the input signal A 204. When the incoming pulse width of the input signal A 204 is greater than the filter time 127, the output signal Y 206 may include the pulse of the input signal A 204. However, other narrow pulse filters struggle when the incoming pulse width of the input signal A 204 is equal to, or approximately equal to, the filter time 127.

When the input signal A 204 changes to a digital logic high, the capacitor C1 210 may begin to charge. If the input signal A 204 then changes to a digital logic low, and the capacitor C1 210 has not yet charged to the inverter up threshold voltage 125a of the Schmitt trigger 218, the output signal Y 206 may remain at a digital logic low (i.e., the narrow pulse in the input signal A 204 is filtered out by the narrow pulse filter 202). Once the capacitor C1 210 reaches the inverter up threshold voltage 125a of the Schmitt trigger 218 (this may be referred to as the filter time 127 of the narrow pulse filter 202), the output signal Y 206 may switch to a digital logic high. If the input signal A 204 then changes to a digital logic low, the capacitor C1 210 may begin discharging. Once the capacitor C1 210 has discharged below the inverter down threshold voltage 125b of the Schmitt trigger 218, the output signal Y 206 may return to a digital logic low.

The Schmitt trigger 218 is used to prevent problems due to charge accumulation in the capacitor C1 210. In an exemplary embodiment of the invention, when the voltage across the capacitor C1 210 and the voltage at the input signal A 204 are both low, a positive pulse can only pass through the narrow pulse filter 202 if the width of the positive pulse is greater than the filter time 127 of the narrow pulse filter 202. However, if the capacitor C1 210 is pre-charged to a voltage that is just below the inverter threshold voltage of the fourth inverter 214d (i.e., in a circuit without the Schmitt trigger 218) and the input signal A 204 is at a digital logic low, a narrow positive pulse may pass through the narrow pulse filter 202. Because the Schmitt trigger 218 has a higher inverter up threshold voltage 125a than the fourth inverter 214d, the narrow positive pulse is prevented from passing through the narrow pulse filter 202.

The pulse generator 212 is included for instances when the incoming pulse width in the input signal A 204 is approximately equal to the filter time 127 of the narrow pulse filter 202. As the voltage across the capacitor C1 210 reaches the inverter up threshold voltage 125a of the Schmitt trigger 218, the latching process may begin. Because the incoming pulse width is approximately equal to the filter time 127 of the narrow pulse filter 202, the input signal A 204 may then switch from a digital high signal to a digital low signal and the capacitor C1 210 may begin discharging. When the voltage across the capacitor C1 210 drops below the inverter down threshold voltage 125b of the Schmitt trigger 218, the latching process stops. Thus, a narrow pulse may be seen at the output signal Y 206.

In the narrow pulse filter 202 with the pulse generator 212, when the latching process begins (i.e., once the voltage across the capacitor C1 210 is equal to the inverter up threshold voltage 125a of the Schmitt trigger 218), the first tri-state inverter 216a is placed in the high-impedance state by a pulse from the pulse generator 212. Thus, the input signal A 204 is temporally disconnected from the resistor R1 208, preventing the capacitor C1 210 from being discharged. When the first tri-state inverter 216a is in the high-impedance state, the second tri-state inverter 216b is operating to either pull Node C 231 to a digital logic high or to a digital logic low. The capacitor C1 210 may charge all the way to the rail voltage. In an exemplary embodiment of the invention, once the capacitor C1 210 has charged to the rail voltage, the first tri-state inverter 216a returns to the previous state (either the digital logic high output state or the digital logic low output state), reconnecting the input signal A 204 with the resistor R1 208. Thus, the output signal Y 206 may include the pulse width that is approximately equal to the filter time 127.

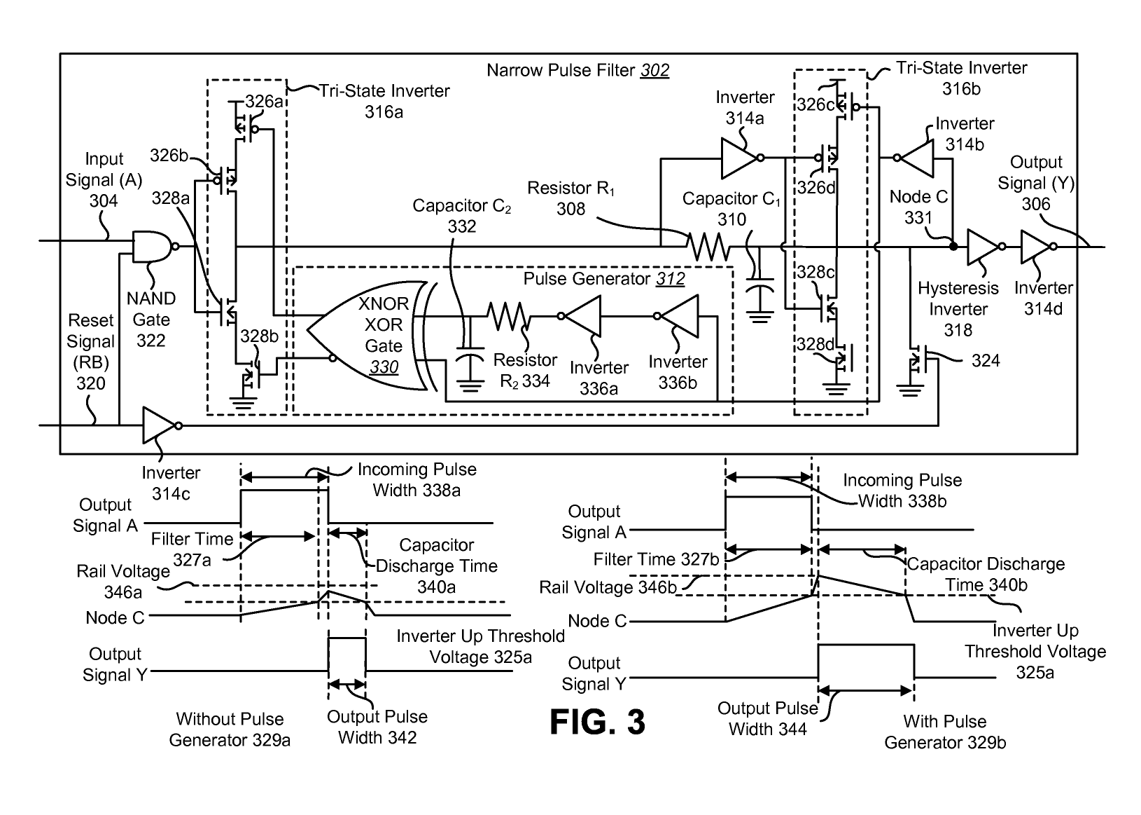

FIG. 3 is a circuit diagram illustrating more specific components of a narrow pulse filter 302. The narrow pulse filter 302 of FIG. 3 may be one configuration of the narrow pulse filter 102 of FIG. 1. The narrow pulse filter 302 may remove or reduce narrow pulses in an input signal A 304. In an exemplary embodiment of the invention, the narrow pulse filter 302 may remove or reduce narrow pulses in an input signal A 304 when the pulse width of the input signal A 304 is approximately equal to the filter time 127 of the narrow pulse filter 302.

The narrow pulse filter 302 may include a NAND gate 322. The NAND gate 322 may receive an input signal A 304 and a reset signal RB 320. The output of the NAND gate 322 may be input to a first tri-state inverter 316a. The first tri-state inverter 316a may include a first P-channel enhanced transistor 326a, a second P-channel enhanced transistor 326b, a first N-channel enhanced transistor 328a and a second N-channel enhanced transistor 328b. The source of the first P-channel enhanced transistor 326a may be coupled to a supply voltage. The gate of the first P-channel enhanced transistor 326a may be coupled to an XNOR/XOR gate 330. The XNOR/XOR gate 330 is a logic gate with two inputs and both an XNOR gate and an XOR gate. The XNOR/XOR gate 330 may be part of a pulse generator 312. The drain of the first P-channel enhanced transistor 326a may be coupled to the source of the second P-channel enhanced transistor 326b. The gate of the second P-channel enhanced transistor 326b may be coupled to the output of the NAND gate 322.

The drain of the second P-channel enhanced transistor 326b may be coupled to the drain of the first N-channel enhanced transistor 328a. The gate of the first N-channel enhanced transistor 328a may also be coupled to the output of the NAND gate 322. Both the drain of the second P-channel enhanced transistor 326b and the drain of the first N-channel enhanced transistor 328a may be coupled to a resistor R1 308.

The source of the first N-channel enhanced transistor 328a may be coupled to the drain of the second N-channel enhanced transistor 328b. The source of the second N-channel enhanced transistor 328b may be coupled to ground. The gate of the second N-channel enhanced transistor 328b may be coupled to an output of the XNOR/XOR gate 330.

As discussed above, the pulse generator 312 may include an XNOR/XOR gate 330. The XNOR/XOR gate 330 may include a first input and a second input. The first input may be coupled to an input of the pulse generator 312. The second input may be coupled to a capacitor C2 332 and a resistor R2 334. The capacitor C2 332 may be coupled between the resistor R2 334 and ground. The resistor R2 334 may be coupled between the capacitor C2 332 and the output of a first pulse generator inverter 336a. The input of the first pulse generator inverter 336a may be coupled to the output of a second pulse generator inverter 336b. The input of the second pulse generator inverter 336b may be coupled to the input of the pulse generator 312.

In an exemplary embodiment of the invention, a tri-state inverter 316 may operate in one of three states: a digital logic high output state, a digital logic low output state and a high-impedance state. The pulse generator 312 may be used to generate a pulse that causes the first tri-state inverter 316a to enter the high-impedance state. When the first tri-state inverter 316a is in the high-impedance state, the input signal A 304 may be disconnected from the resistor R1 308 (i.e., the input signal A 304 may have no influence on the resistor R1 308).

The resistor R1 308 may be coupled to a capacitor C1 310. The capacitor C1 310 may also be coupled to ground. Both the resistor R1 308 and the capacitor C1 310 may be coupled to a Node C 331. The resistor R1 308 may also be coupled to an input of a first inverter 314a. The output of the first inverter 314a may be coupled to a second tri-state inverter 316b.

The second tri-state inverter 316b may include a third P-channel enhanced transistor 326c, a fourth P-channel enhanced transistor 326d, a third N-channel enhanced transistor 328c and a fourth N-channel enhanced transistor 328d. The source of the third P-channel enhanced transistor 326c may be coupled to a supply voltage. The gate of the third P-channel enhanced transistor 326c may be coupled to the input of the pulse generator 312. The drain of the third P-channel enhanced transistor 326c may be coupled to the source of the fourth P-channel enhanced transistor 326d. The gate of the fourth P-channel enhanced transistor 326d may be coupled to the output of the first inverter 314a.

The drain of the fourth P-channel enhanced transistor 326d may be coupled to the drain of the third N-channel enhanced transistor 328c. The gate of the third N-channel enhanced transistor 328c may also be coupled to the output of the first inverter 314a. Both the drain of the fourth P-channel enhanced transistor 326d and the drain of the third N-channel enhanced transistor 328c may be coupled to the Node C 331.

The source of the third N-channel enhanced transistor 328c may be coupled to the drain of the fourth N-channel enhanced transistor 328d. The source of the fourth N-channel enhanced transistor 328d may be coupled to ground. The gate of the fourth N-channel enhanced transistor 328d may also be coupled to the input of the pulse generator 312.

The Node C 331 may be coupled to the input of a second inverter 314b. The output of the second inverter 314b may be coupled to the input of the pulse generator 312. The Node C 331 may also be coupled to the drain of an N-channel enhanced transistor 324. The source of the N-channel enhanced transistor 324 may be coupled to ground. The gate of the N-channel enhanced transistor 324 may be coupled to an output of a third inverter 314c. The third inverter 314c may receive the reset signal RB 320 as an input. The reset signal RB 320 may be a digital logic high during normal operation and a digital logic low when a reset of the narrow pulse filter 302 is desired.

The Node C 331 may also be coupled to the input of a threshold circuit. In one configuration, the threshold circuit may be a hysteresis inverter 318 or a Schmitt trigger 118. The hysteresis inverter 318 may have a higher inverter up threshold voltage 125a than the other inverters 114 of the narrow pulse filter 302. The output of the hysteresis inverter 318 may be input to a fourth inverter 314d. The output of the fourth inverter 314d may be the output signal Y 306.

Waveforms for the input signal A 304, the Node C 331 and the output signal Y 306 are illustrated for a narrow pulse filter with the pulse generator 329b in an exemplary embodiment of the invention and a narrow pulse filter without the pulse generator 327a. Specifically, the output signal Y 306 is illustrated for an incoming pulse width 338a that is approximately equal to (but slightly longer than) the filter time 127 of the narrow pulse filter 302. If the incoming pulse width 338a is approximately equal but slightly shorter than the filter time 127 of the narrow pulse filter 302, then an output pulse is never created because Node C 331 does not reach the inverter up threshold voltage 325a.

When the input signal A 304 switches from a digital logic low to a digital logic high, the voltage at Node C 331 may begin to charge. Once the voltage at the Node C 331 reaches the inverter threshold voltage 325a, the voltage at Node C 331 may charge up at a faster rate toward the rail voltage 346a (because the output of the second tri-state inverter 316b pulls up Node C 331 directly, and not through the resistor R1 308 as the first tri-state inverter 316a). The pulse generator 312 only prevents the first tri-state inverter 316a or the input signal (A) 304 from discharging the Node C 331.

In the narrow pulse filter without the pulse generator 329a, if the input signal A 304 switches from a digital logic high to a digital logic low before the voltage at Node C 331 has hit the rail voltage 346a (e.g., if the incoming pulse width 338a is approximately equal to the filter time 327a), the capacitor C1 310 may begin to discharge. Because the capacitor C1 310 has not been charged to the rail voltage 346, the capacitor discharge time 340a may be less than the filter time 327a. Thus, the output signal Y 306 may include a narrow output pulse width 342 that is undesirable.

In an exemplary embodiment of the invention, specifically the narrow pulse filter with the pulse generator 329b, the capacitor C1 331 may charge to the rail voltage 346b at a higher rate after reaching the inverter threshold voltage 325a, due to the second tri-state inverter 316b pulling it up directly. Thus, when the input signal A 304 switches from a digital logic high to a digital logic low, the voltage at Node C 331 is the rail voltage 346b (e.g., the incoming pulse width 338b is approximately equal to the filter time 327b) and the capacitor discharge time 340b equals the filter time 320b. The output signal Y 306 may include a pulse with the appropriate output pulse width 344.

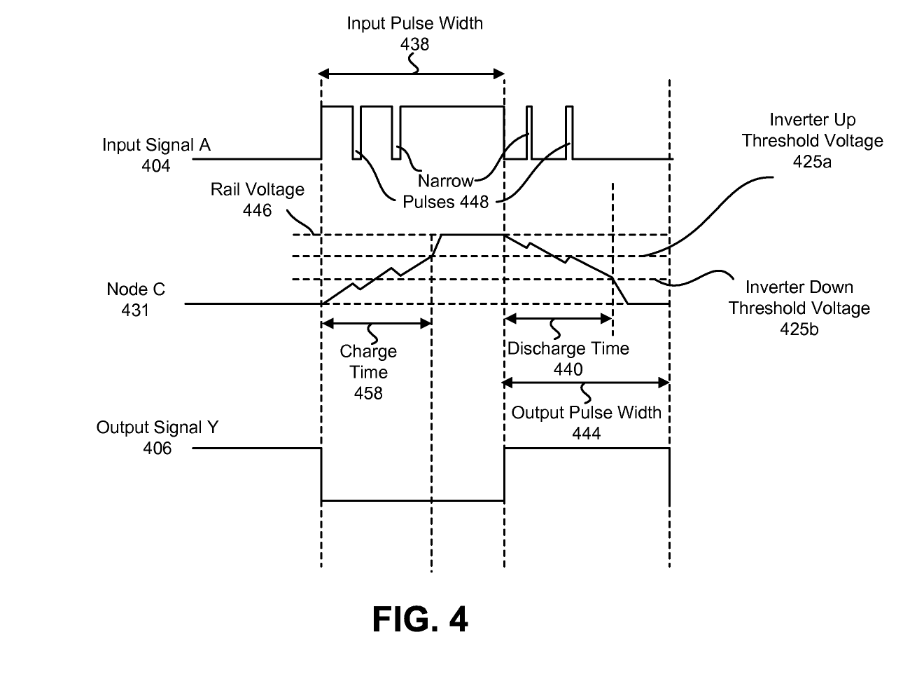

FIG. 4 is a timing diagram illustrating waveforms for the input signal A 404, the Node C 431 and the output signal Y 406. The input signal A 404 may have an input pulse width 438 with multiple narrow pulses 448. It may be desirable to filter out the narrow pulses 448 within the input signal A 404 to obtain the output signal Y 406 without the narrow pulses 448.

The Node C 431 may reflect the voltage across the capacitor C1 210. Initially, the voltage at the Node C 431 may be 0. When the input signal A 404 switches from a digital logic low to a digital logic high, the capacitor C1 210 may begin to charge. If the input signal A 404 includes a narrow pulse 448, the capacitor C1 210 may slightly discharge. Once the Node C 431 voltage reaches the inverter up threshold voltage 425a (i.e., the charge time 458, which is also referred to herein as the filter time 127), the capacitor C1 210 may be pulled up to the rail voltage 446 by the second tri-state inverter 216b while the first tri-state inverter 216a is in the high-impedance state (and thus the input signal A 404 does not affect the Node C 431). After the Node C 431 reaches the rail voltage 446, the first tri-state inverter 216a may return to outputting a digital logic high signal. At this point, the second tri-state inverter 216b is tri-stated so that a low pulse event might be started. The output signal Y 406 may include a pulse with an output pulse width 444 that is equal to the incoming pulse width 438 without the narrow pulses 448.

When the input signal A 404 switches from a digital logic high to a digital logic low, the capacitor C1 210 may begin to discharge. Once the voltage at Node C 431 falls below the inverter down threshold voltage 425b (after the discharge time 440), the first tri-state inverter 216a may enter the high-impedance state (thus removing the connection between the input signal A 404 and the Node C 431) and the second tri-state inverter 216b may pull down the voltage at Node C 431 to 0 volts. After the Node C 431 reaches 0 volts, the first tri-state inverter 216a may return to outputting a digital logic low signal. The second tri-state inverter 216b may also return to outputting a digital logic low signal.

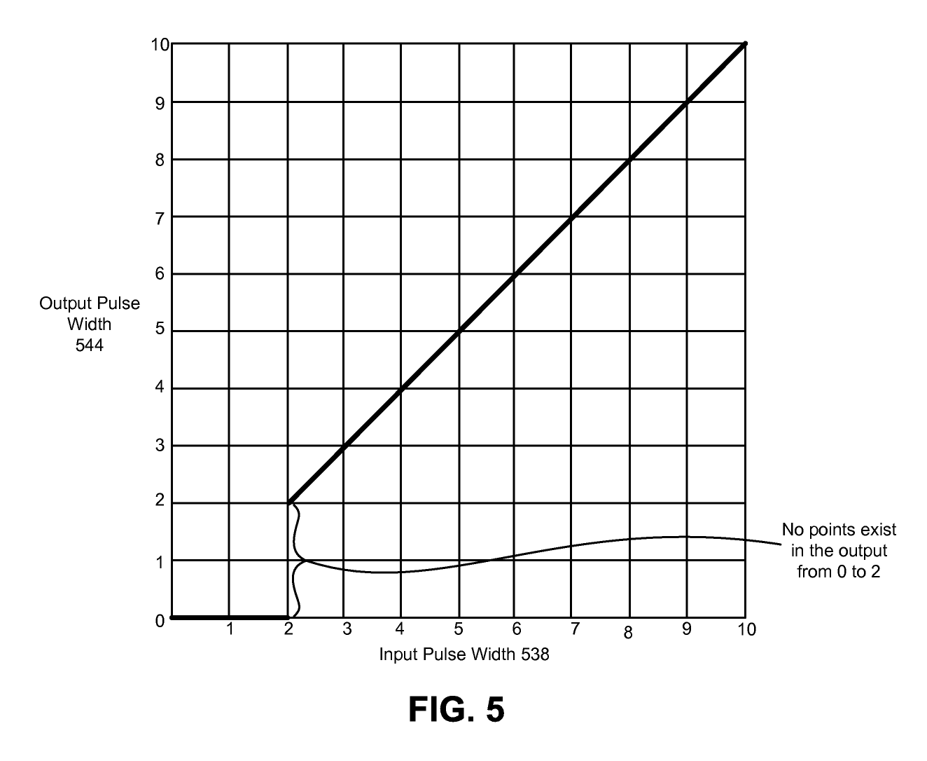

FIG. 5 is a block diagram illustrating the ideal transfer function of a narrow pulse filter 202. The input pulse width 538 is measured against the output pulse width 544. If the input pulse width 538 is less than 2 (in this exemplary embodiment), the output pulse width 544 should be zero. Once the input pulse width 538 equals 2, the output pulse width 544 should also be 2. When the input pulse width 538 is greater than 2, the output pulse width 544 should increase linearly with the input pulse width 538.

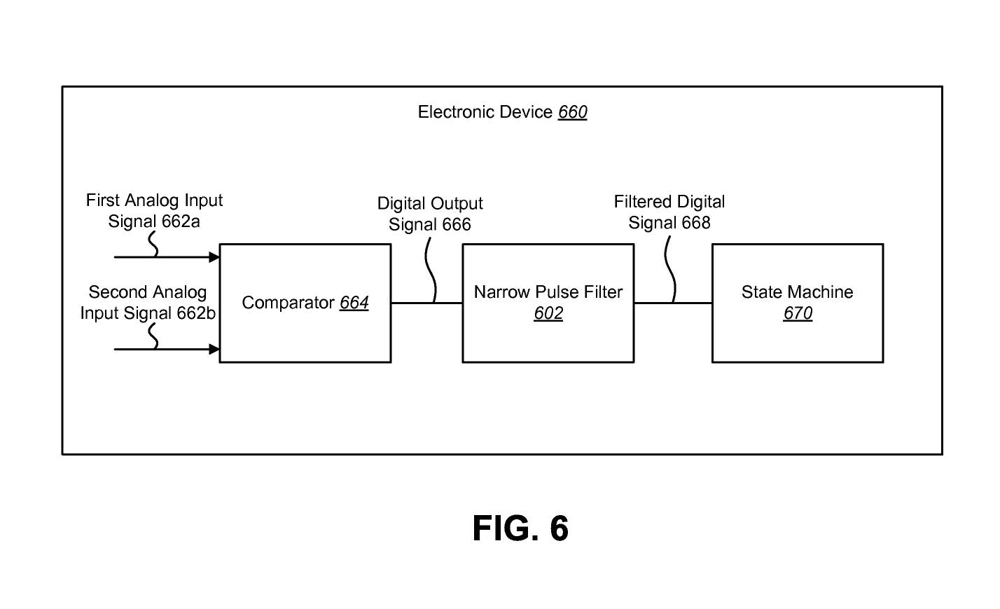

FIG. 6 is a block diagram illustrating an electronic device 660 for use in the present systems and methods. The electronic device 660 may include a comparator 664, a narrow pulse filter 602 and a state machine 670. The narrow pulse filter 602 of FIG. 6 may be one configuration of the narrow pulse filter 102 of FIG. 1. The electronic device 660 may be a base station, a wireless communication device, etc.

In an exemplary embodiment of the invention, the comparator 664 may receive a first analog input signal 662a and a second analog input signal 662b. The comparator 664 may then output a digital output signal 666. The digital output signal 666 may contain glitches in the form of narrow pulses 448 due to a noisy inductive switching environment. If left unmitigated, these narrow pulses 448 may damage the state machine 670 or cause faulty operation. Thus, the digital output signal 666 may be passed through the narrow pulse filter 602 to obtain a filtered digital signal 668. In an exemplary embodiment, the filtered digital signal 668 may include the digital output signal 666 without the narrow pulses 448. The filtered digital signal 668 may then be input to the state machine 670.

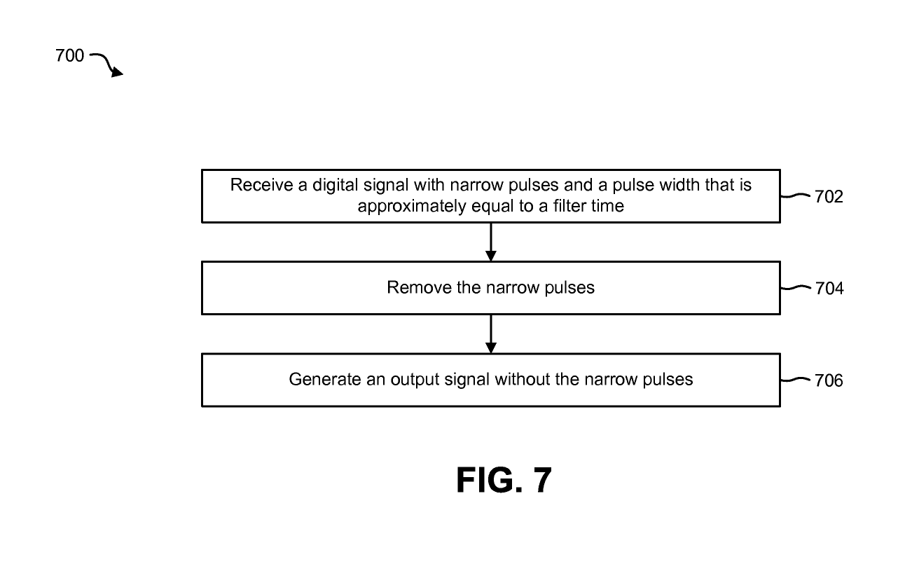

FIG. 7 is a flow diagram of a method 700 for filtering narrow pulses 448. The method 700 may be performed by a narrow pulse filter 102. In one embodiment of the invention, the narrow pulse filter 102 may be located on an electronic device 660. The narrow pulse filter 102 may receive 702 a digital signal 104 with narrow pulses 448 and a pulse width 438 that is approximately equal to a filter time 127 of the narrow pulse filter 102. The narrow pulse filter 102 may remove 704 the narrow pulses 448. As discussed above, the narrow pulse filter 102 may remove the narrow pulses 448 using a pulse generator 112, multiple tri-state inverters 116, multiple inverters 114, a resistor R1 208 and a capacitor C1 210. The narrow pulse filter 102 may then generate 706 an output signal 206 without the narrow pulses 448.

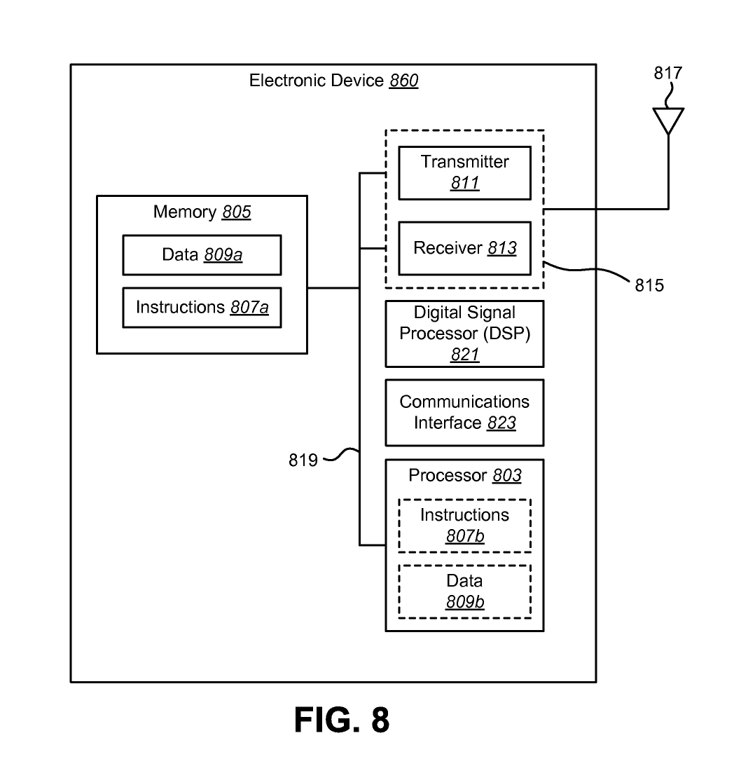

FIG. 8 illustrates certain components that may be included within an exemplary electronic device 860. The electronic device 860 may be a base station, an access point, a NodeB, an evolved NodeB, a wireless communication device, a user equipment (UE), an access terminal or any other electronic device with digital signals. The electronic device 860 includes a processor 803. The processor 803 may be a general purpose single- or multi-chip microprocessor (e.g., an ARM), a special purpose microprocessor (e.g., a digital signal processor (DSP)), a microcontroller, a programmable gate array, etc. The processor 803 may be referred to as a central processing unit (CPU). Although just a single processor 803 is shown in the electronic device 860 of FIG. 8, in an alternative configuration, a combination of processors (e.g., an ARM and DSP) could be used.

The exemplary electronic device 860 also includes memory 805. The memory 805 may be any electronic component capable of storing electronic information. The memory 805 may be embodied as random access memory (RAM), read-only memory (ROM), magnetic disk storage media, optical storage media, flash memory devices in RAM, on-board memory included with the processor, EPROM memory, EEPROM memory, registers, and so forth, including combinations thereof.

Data 809a and instructions 807a may be stored in the memory 805. The instructions 807a may be executable by the processor 803 to implement the methods disclosed herein. Executing the instructions 807a may involve the use of the data 809a that is stored in the memory 805. When the processor 803 executes the instructions 807a, various portions of the instructions 807b may be loaded onto the processor 803, and various pieces of data 809b may be loaded onto the processor 803.

The exemplary electronic device 860 may also include a transmitter 811 and a receiver 813 to allow transmission and reception of signals to and from the electronic device 860 using an antenna 817. The transmitter 811 and receiver 813 may be collectively referred to as a transceiver 815. The exemplary electronic device 860 may also include (not shown) multiple transmitters, multiple receivers and/or multiple transceivers. The exemplary electronic device 860 may also include a digital signal processor (DSP) 821 and a communications interface 823.

The various components of the exemplary electronics device 860 may be coupled together by one or more buses, which may include a power bus, a control signal bus, a status signal bus, a data bus, etc. For the sake of clarity, the various buses are illustrated in FIG. 8 as a bus system 819.

Those of skill in the art would understand that information and signals may be represented using any of a variety of different technologies and techniques. For example, data, instructions, commands, information, signals, bits, symbols and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits and algorithm steps described in connection with the embodiments disclosed herein may be implemented as electronic hardware, computer software or combinations of both. To clearly illustrate this interchangeability of hardware and software, various illustrative components, blocks, modules, circuits and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules and circuits described in connection with the embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in Random Access Memory (RAM), flash memory, Read-Only Memory (ROM), Electrically Programmable ROM (EPROM), Electrically Erasable Programmable ROM (EEPROM), registers, hard disk, a removable disk, a CD-ROM or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary embodiments, the functions described may be implemented in hardware, software, firmware or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server or other remote source using a coaxial cable, fiber optic cable, twisted pair, digital subscriber line (DSL) or wireless technologies such as infrared, radio and microwave, then the coaxial cable, fiber optic cable, twisted pair, DSL or wireless technologies such as infrared, radio and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The term “processor” should be interpreted broadly to encompass a general purpose processor, a central processing unit (CPU), a microprocessor, a digital signal processor (DSP), a controller, a microcontroller, a state machine and so forth. Under some circumstances, a “processor” may refer to an application specific integrated circuit (ASIC), a programmable logic device (PLD), a field programmable gate array (FPGA), etc. The term “processor” may refer to a combination of processing devices, e.g., a combination of a DSP and a microprocessor, a plurality of microprocessors, one or more microprocessors in conjunction with a DSP core, or any other such configuration.

The term “memory” should be interpreted broadly to encompass any electronic component capable of storing electronic information. The term memory may refer to various types of processor-readable media such as random access memory (RAM), read-only memory (ROM), non-volatile random access memory (NVRAM), programmable read-only memory (PROM), erasable programmable read-only memory (EPROM), electrically erasable PROM (EEPROM), flash memory, magnetic or optical data storage, registers, etc. Memory is said to be in electronic communication with a processor if the processor can read information from and/or write information to the memory. Memory that is integral to a processor is in electronic communication with the processor.

The terms “instructions” and “code” should be interpreted broadly to include any type of computer-readable statement(s). For example, the terms “instructions” and “code” may refer to one or more programs, routines, sub-routines, functions, procedures, etc. “Instructions” and “code” may comprise a single computer-readable statement or many computer-readable statements.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

Further, it should be appreciated that modules and/or other appropriate means for performing the methods and techniques described herein, such as those illustrated by FIG. 7, can be downloaded and/or otherwise obtained by a device. For example, a device may be coupled to a server to facilitate the transfer of means for performing the methods described herein. Alternatively, various methods described herein can be provided via a storage means (e.g., random access memory (RAM), read-only memory (ROM), a physical storage medium such as a compact disc (CD) or floppy disk, etc.), such that a device may obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes and variations may be made in the arrangement, operation and details of the systems, methods and apparatus described herein without departing from the scope of the claims.

What is claimed is:

1. A narrow pulse filter, comprising:
a first tri-state inverter; and
a pulse generator coupled to the first tri-state inverter, the pulse generator configured to cause the first tri-state inverter to enter a high-impedance state to filter out a narrow pulse from a signal input to the first tri-state inverter.

2. The narrow pulse filter of claim 1, wherein the narrow pulse filter generates an output signal with the narrow pulse removed at an output node.

3. The narrow pulse filter of claim 2, further comprising a threshold circuit coupled between a resistor-capacitor circuit and the output node.

4. The narrow pulse filter of claim 3, wherein the threshold circuit is a Schmitt trigger.

5. The narrow pulse filter of claim 3, wherein the threshold circuit is an inverter with hysteresis.

6. The narrow pulse filter of claim 3, wherein the threshold circuit has higher threshold voltages than inverters in the narrow pulse filter.

7. The narrow pulse filter of claim 3, wherein the threshold circuit prevents a positive narrow pulse from passing through the narrow pulse filter when the capacitor is pre-charged to a voltage that is below a threshold voltage of the threshold circuit and an initial input voltage is zero.

8. The narrow pulse filter of claim 3, further comprising a second tri-state inverter, wherein the second tri-state inverter is coupled between the threshold circuit and the pulse generator.

9. The narrow pulse filter of claim 8, wherein the second tri-state inverter pulls a voltage across the resistor-capacitor circuit up to a rail voltage or down to zero when the first tri-state inverter is in the high-impedance state.

10. The narrow pulse filter of claim 1, wherein each tri-state inverter comprises a first N-channel enhanced transistor, a second N-channel enhanced transistor, a first P-channel transistor and a second P-channel transistor.

11. The narrow pulse filter of claim 1, wherein the pulse generator comprises:
an XNOR/XOR gate coupled to the first tri-state inverter;
a capacitor coupled to a first input of the XNOR/XOR gate;
a resistor coupled to the input of XNOR/XOR gate;
a first inverter coupled to the resistor; and
a second inverter coupled to the first inverter.

12. The narrow pulse filter of claim 11, wherein an output of the first inverter is coupled to an input of the second inverter, wherein an output of the second inverter is coupled to the resistor, wherein the capacitor is coupled between the resistor and ground, wherein a second input to the XNOR/XOR gate is coupled to both an input of the first inverter and a second tri-state inverter, and wherein an output of the XNOR/XOR gate is coupled to the first tri-state inverter.

13. The narrow pulse filter of claim 1, wherein the pulse generator prevents a narrow pulse from being generated when an input pulse width of an input signal is approximately equal to a filter time of the narrow pulse filter.

14. The narrow pulse filter of claim 1, wherein an input signal is disconnected from the resistor-capacitor circuit when the first tri-state inverter is in the high-impedance state.

15. A method for filtering narrow pulses, the method comprising:
receiving an input signal having a pulse width that is approximately equal to a filter time;
filtering a narrow pulse from the input signal; and
generating an output signal not having the narrow pulse.

16. The method of claim 15, wherein the output signal is a delayed version of the input signal without any narrow pulses.

17. The method of claim 15, wherein the input signal is a digital signal.

18. An apparatus configured for filtering narrow pulses, comprising:
means for receiving an input signal having a pulse width that is approximately equal to a filter time;
means for filtering a narrow pulse from the input signal; and
means for generating an output signal not having the narrow pulse.
